(19) United States
(12) Patent Application Publication
(10) Pub. No.: US 2025/0242592 A1
(43) Pub. Date: Jul. 31, 2025

(54) PIEZOELECTRIC ELEMENT, LIQUID EJECTION HEAD, AND PRINTER

(71) Applicant: SEIKO EPSON CORPORATION, Tokyo (JP)

(72) Inventors: Shu OKADA, SUWA-SHI (JP); Yoshiki YANO, CHINO-SHI (JP); Tsukasa HITOMI, CHINO-SHI (JP)

(21) Appl. No.: 19/039,469

(22) Filed: Jan. 28, 2025

(30) Foreign Application Priority Data
Jan. 31, 2024 (JP) 2024-012655

(51) Int. Cl. B41J 2/14; C01G 33/00; H10N 30/00; H10N 30/20; H10N 30/50; H10N 30/853

(52) U.S. Cl. CPC B41J 2/14233; C01G 33/006; H10N 30/2047; H10N 30/50; H10N 30/708; H10N 30/8542; B41J 2002/14258; B41J 2002/14306; C01P 2002/34; C01P 2002/76; C01P 2006/40

(57) ABSTRACT

A piezoelectric element includes: a first electrode; a piezoelectric layer provided above the first electrode and containing a perovskite-type complex oxide containing potassium, sodium, and niobium; and a second electrode provided on or above the piezoelectric layer. The piezoelectric layer is preferentially oriented in a (100) plane, and a full width at half maximum of a peak derived from the (100) plane measured by an X-ray rocking curve method is 3.193° or less.

The present application is based on, and claims priority from JP Application Serial Number 2024-012655, filed Jan. 31, 2024, the disclosure of which is hereby incorporated by reference herein in its entirety.

### BACKGROUND

### 1. Technical Field

The present disclosure relates to a piezoelectric element, a liquid ejection head, and a printer.

### 2. Related Art

A piezoelectric element used in a liquid ejection head or the like of an inkjet printer is implemented by, for example, sandwiching a piezoelectric layer made of a piezoelectric material having an electromechanical conversion function between two electrodes.

For example, JP-A-2018-133458 discloses a piezoelectric element including a thin-film piezoelectric layer made of a perovskite type complex oxide containing potassium, sodium, and niobium.

In the piezoelectric element as described above, it is desired to improve piezoelectric characteristics.

### SUMMARY

A piezoelectric element according to an aspect of the present disclosure includes: a first electrode; a piezoelectric layer provided above the first electrode and containing a perovskite-type complex oxide containing potassium, sodium, and niobium; and a second electrode provided on or above the piezoelectric layer. The piezoelectric layer is preferentially oriented in a (100) plane, and a full width at half maximum of a peak derived from the (100) plane measured by an X-ray rocking curve method is 3.193° or less.

A liquid ejection head according to an aspect of the present disclosure includes: the piezoelectric element; a flow path forming substrate formed with a pressure generating chamber having a volume changed by the piezoelectric element; and a nozzle plate having a nozzle hole which is formed therein and communicates with the pressure generating chamber.

A printer according to an aspect of the present disclosure includes: the liquid ejection head; a conveyance mechanism configured to move a recording medium relative to the liquid ejection head; and a control unit configured to control the liquid ejection head and the conveyance mechanism.

### BRIEF DESCRIPTION OF THE DRAWINGS

FIG. 1 is a cross-sectional view schematically showing a piezoelectric element according to an embodiment.

FIG. 2 is an exploded perspective view schematically showing a liquid ejection head according to the embodiment.

FIG. 3 is a plan view schematically showing the liquid ejection head according to the embodiment.

FIG. 4 is a cross-sectional view schematically showing the liquid ejection head according to the embodiment.

FIG. 5 is a perspective view schematically showing a printer according to the embodiment.

FIG. 6 shows results of proton NMR measurement of niobium 2-ethylhexanoate used in a KNN precursor solution.

FIG. 7 is a table showing experimental results of Examples 1 and 2 and Comparative Examples 1 and 2.

### DESCRIPTION OF EMBODIMENTS

Hereinafter, a preferred embodiment according to the present disclosure will be described in detail with reference to the drawings. The embodiment to be described below does not unduly limit contents of the present disclosure described in the claims. All the configurations to be described below are not necessarily essential elements of the present disclosure.

### 1. Piezoelectric Element

### 1.1. Configuration

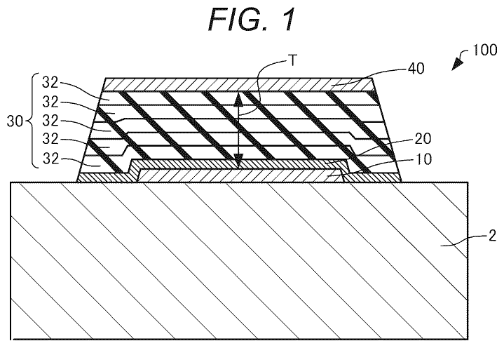

First, a piezoelectric element according to the embodiment will be described with reference to the drawings. FIG. 1 is a cross-sectional view schematically showing a piezoelectric element 100 according to the embodiment.

As shown in FIG. 1, the piezoelectric element 100 includes, for example, a first electrode 10, an orientation control layer 20, a piezoelectric layer 30, and a second electrode 40. The piezoelectric element 100 is provided on a substrate 2.

The substrate 2 is a flat plate formed of, for example, a semiconductor or an insulator. The substrate 2 may be a single layer, or a stack where a plurality of layers are stacked. An internal structure of the substrate 2 is not limited as long as an upper surface has a planar shape, and the substrate 2 may have a structure in which a space or the like is formed therein.

The substrate 2 may include a vibration plate that is deformed by an operation of the piezoelectric layer 30. The vibration plate is, for example, a silicon oxide layer, a zirconium oxide layer, or a stack in which a zirconium oxide layer is provided on a silicon oxide layer.

The first electrode 10 is provided on the substrate 2. The first electrode 10 is provided between the substrate 2 and the orientation control layer 20. The first electrode 10 has, for example, a layered shape. A thickness of the first electrode 10 is, for example, 5 nm or more and 300 nm or less, and preferably 50 nm or more and 200 nm or less.

The first electrode 10 is, for example, a titanium layer, a platinum layer, or an iridium layer. The first electrode 10 may be formed by stacking a titanium layer, a platinum layer, and an iridium layer in this order from a substrate 2 side. The titanium layer improves, for example, adhesion between the substrate 2 and the platinum layer. The first electrode 10 is one electrode for applying a voltage to the piezoelectric layer 30.

The orientation control layer 20 is provided on the first electrode 10. The orientation control layer 20 is provided between the first electrode 10 and the piezoelectric layer 30. In the illustrated example, the orientation control layer 20 is further provided on the substrate 2. A thickness of the orientation control layer 20 is, for example, 5 nm or more and 100 nm or less, and preferably 10 nm or more and 50 nm or less.

The orientation control layer 20 includes, for example, a complex oxide having a perovskite type structure containing bismuth (Bi), iron (Fe), titanium (Ti), and lead (Pb). The orientation control layer 20 is, for example, a bismuth lead ferrite titanate ((Bi, Pb) (Fe, Ti) 03: BFTP) layer. The orientation control layer 20 may be a BFTP layer with an additive. The orientation control layer 20 controls an orientation of the piezoelectric layer 30.

The piezoelectric layer 30 is provided above the first electrode 10. In the illustrated example, the piezoelectric layer 30 is provided on the orientation control layer 20. The piezoelectric layer 30 is provided between the first electrode 10 and the second electrode 40. In the illustrated example, the piezoelectric layer 30 is provided between the orientation control layer 20 and the second electrode 40. A thickness T of the piezoelectric layer 30 is, for example, 100 nm or more and 3000 nm or less, preferably 200 nm or more and 2000 nm or less, and more preferably 600 nm or more and 1000 nm or less. The thickness T of the piezoelectric layer 30 is measured by spectroscopic ellipsometry. The piezoelectric layer 30 has columnar crystals extending in a thickness direction of the piezoelectric layer 30 (hereinafter, also simply referred to as “thickness direction”). The piezoelectric layer 30 is deformed by being applied with a voltage between the first electrode 10 and the second electrode 40.

The piezoelectric layer 30 includes, for example, a plurality of crystal layers 32. The piezoelectric layer 30 is formed by, for example, the plurality of crystal layers 32. The number of crystal layers 32 is, for example, 2 or more and 30 or less, and preferably 3 or more and 20 or less. In the illustrated example, five crystal layers 32 are provided. A thickness of the crystal layer 32 is, for example, 10 nm or more and 200 nm or less, and preferably 30 nm or more and 150 nm or less.

The crystal layer 32 is a layer containing a complex oxide having a perovskite type structure containing potassium (K), sodium (Na), and niobium (Nb). The crystal layer 32 is, for example, a potassium sodium niobate ((K, Na) NbO₃: KNN) layer. The crystal layer 32 may be a KNN layer with an additive. Examples of the additive include lithium (Li), manganese (Mn), and copper (Cu). A content of the additive in the crystal layer 32 is, for example, 10 mol % or less, and preferably 5 mol % or less. The additive may be unevenly distributed in grain boundaries of the crystal layers 32.

The second electrode 40 is provided on or above the piezoelectric layer 30. In the illustrated example, the second electrode 40 is provided on the piezoelectric layer 30. Although not illustrated, the second electrode 40 may be further provided at a side surface of the piezoelectric layer 30 and on the substrate 2 as long as the second electrode 40 is electrically separated from the first electrode 10. The second electrode 40 has, for example, a layered shape. A thickness of the second electrode 40 is, for example, 15 nm or more and 300 nm or less.

The second electrode 40 is, for example, a platinum layer, a titanium layer, or an iridium layer. The second electrode 40 may be formed by stacking a plurality of layers exemplified above. The second electrode 40 is another electrode for applying a voltage to the piezoelectric layer 30.

### 1.2. X-Ray Diffraction

The piezoelectric layer 30 is preferentially oriented in a (100) plane. The term “preferentially oriented” means that 70% or more, preferably 80% or more of crystals are oriented in a predetermined crystal plane. The expression “preferentially oriented in the (100) plane” includes a case where all crystals of the piezoelectric layer 30 are oriented in the (100) plane and a case where 70% or more, preferably 80% or more of the crystals are oriented in the (100) plane. Whether the piezoelectric layer 30 is preferentially oriented in the (100) plane is confirmed by performing X-ray diffraction (XRD) on the piezoelectric layer 30.

In the piezoelectric layer 30, a full width at half maximum (FWHM) of a peak derived from the (100) plane measured by an X-ray rocking curve method is 3.193° or less, preferably 3.150° or less, more preferably 3.140° or less, and still more preferably 3.133° or less. When the full width at half maximum of the peak derived from the (100) plane is 3.193° or less, crystallinity of the piezoelectric layer 30 can be improved. In the piezoelectric layer 30, the full width at half maximum of the peak derived from the (100) plane measured by the X-ray rocking curve method is, for example, 2.0° or more.

In the piezoelectric layer 30, an integrated intensity of the peak derived from the (100) plane measured by the X-ray rocking curve method is, for example, 2.5×10⁴ cps or more, preferably 2.8×10⁴ cps or more, and more preferably 2.81×10⁴ cps or more. When the integrated intensity of the peak derived from the (100) plane is 2.5×10⁴ cps or more, an orientation of the piezoelectric layer 30 in the (100) plane can be improved. In the piezoelectric layer 30, the integrated intensity of the peak derived from the (100) plane measured by the X-ray rocking curve method is, for example, 4.0×10⁴ cps or less.

The integrated intensity of the peak derived from the (100) plane measured by the X-ray rocking curve method to the thickness T of the piezoelectric layer 30 is, for example, 70.0 cps/nm or more, preferably 70.5 cps/nm or more, and more preferably 70.65 cps/nm or more. When the integrated intensity of the peak derived from the (100) plane to the thickness T is 70.0 cps/nm or more, the orientation of the piezoelectric layer 30 in the (100) plane can be improved. The integrated intensity of the peak derived from the (100) plane measured by the X-ray rocking curve method to the thickness T is, for example, 100.0 cps/nm or less.

The piezoelectric layer 30 has a tetragonal crystal structure. The crystal structure of the piezoelectric layer 30 is measured by X-ray diffraction. The crystal structure of the piezoelectric layer 30 is, for example, a tetragonal crystal represented by a=c≠b and a>b where a, b, and c are lattice constants. a/b is, for example, 1.0280 or more, and preferably 1.0285 or more. When a/b is 1.0280 or more, the full width at half maximum of the peak derived from the (100) plane measured by the X-ray rocking curve method can be reduced. In XRD using Cu as a tube, two or more peaks are observed between 20=44° to 47°, and a/b can be obtained based on a ratio when a larger one of an inter-planar spacing obtained from the largest peak and the second largest peak according to the Bragg equation was defined as a numerator and a smaller one was defined as a denominator.

Specifically, of the two peaks existing in the range of 44° to 47°, a low-angle peak side shows a lattice in which “a” stands in a film thickness direction, and a high-angle peak side shows a lattice in which “b” stands in the film thickness direction.

When the thickness T of the piezoelectric layer 30 is measured at 16 points, a value calculated by (maximum value-minimum value)/arithmetic average value×100 for the measured thickness T is, for example, 2.90 or less, preferably 2.50 or less, and more preferably 2.168 or less. When a value calculated by (maximum value-minimum value)/average value×100 is 2.90 or less, a variation in thickness T of the piezoelectric layer 30 can be reduced. When the thickness T of the piezoelectric layer 30 is measured at 16 points, a value calculated by (maximum value−minimum value)/arithmetic average value×100 for the measured thickness T is, for example, 1.0 or more.

### 1.3. Operation and Effect

The piezoelectric element 100 includes: the first electrode 10; the piezoelectric layer 30 provided above the first electrode 10 and containing a perovskite-type complex oxide containing potassium, sodium, and niobium; and the second electrode 40 provided at the upper part of the piezoelectric layer 30. The piezoelectric layer 30 is preferentially oriented in the (100) plane, and a full width at half maximum of a peak derived from the (100) plane measured by an X-ray rocking curve method is 3.193° or less.

Therefore, the piezoelectric element 100 can have high crystallinity, for example, as compared with a case where a full width at half maximum of a peak derived from the (100) plane measured by the X-ray rocking curve method is larger than 3.193°. Accordingly, the piezoelectric characteristics can be improved. Specifically, a piezoelectric constant can be improved.

In the piezoelectric element 100, an integrated intensity of a peak derived from the (100) plane to the thickness T of the piezoelectric layer 30 is 70.65 cps/nm or more. Therefore, in the piezoelectric element 100, the orientation of the piezoelectric layer 30 in the (100) plane can be improved.

In the piezoelectric element 100, a crystal structure of the perovskite-type complex oxide is a tetragonal crystal represented by a=c≠b and a>b, where a, b, and c are lattice constants, and a/b is 1.0285 or more. Therefore, in the piezoelectric element 100, the full width at half maximum of the peak derived from the (100) plane of the piezoelectric layer 30 measured by the X-ray rocking curve method can be reduced.

In the piezoelectric element 100, when the thickness T of the piezoelectric layer 30 is measured at 16 points, a value calculated by (maximum value-minimum value)/average value×100 for the measured thickness T is 2.168 or less. Therefore, in the piezoelectric element 100, a variation in the thickness T of the piezoelectric layer 30 can be reduced.

The piezoelectric element 100 further includes the orientation control layer 20 provided between the first electrode 10 and the piezoelectric layer 30 and containing bismuth, iron, titanium, and lead. Therefore, in the piezoelectric element 100, the orientation of the piezoelectric layer 30 can be controlled.

### 2. Method of Manufacturing Piezoelectric Element

Next, a method of manufacturing the piezoelectric element 100 according to the embodiment will be described with reference to the drawings.

As shown in FIG. 1, the substrate 2 is prepared. Specifically, a silicon oxide layer is formed by thermally oxidizing a silicon substrate. Next, a zirconium layer is formed on the silicon oxide layer by a sputtering method or the like, and the zirconium layer is thermally oxidized to form a zirconium oxide layer. The substrate 2 can be prepared by the above steps.

Next, the first electrode 10 is formed on the substrate 2. The first electrode 10 is formed by, for example, a sputtering method or a vacuum deposition method. Next, the first electrode 10 is patterned, for example, by photolithography and etching.

Next, the orientation control layer 20 is formed on the first electrode 10 and the substrate 2. The orientation control layer 20 is formed by, for example, a chemical solution deposition (CSD) method such as a sol-gel method or a metal organic deposition (MOD) method.

Specifically, first, a BFTP precursor solution is prepared by dissolving or dispersing a metal complex containing bismuth, a metal complex containing iron, a metal complex containing titanium, and a metal complex containing lead in an organic solvent. Next, the BFTP precursor solution is applied onto the first electrode 10 by spin coating to form a BFTP precursor layer. Next, the BFTP precursor layer is heated, for example, at 130° C. or higher and 250° C. or lower and dried for a certain period of time, and the dried BFTP precursor layer is further heated, for example, at 300° C. or higher and 450° C. or lower and held for a certain period of time to be degreased. Next, the degreased BFTP precursor layer is crystallized by firing at, for example, 550° C. or higher and 800° C. or lower. As described above, the orientation control layer 20 made of the BFTP layer can be formed.

Next, the piezoelectric layer 30 is formed on the orientation control layer 20. The piezoelectric layer 30 is formed by, for example, a CSD method.

Specifically, first, for example, a metal complex containing potassium, a metal complex containing sodium, and a metal complex containing niobium are dissolved or dispersed in an organic solvent to prepare a KNN precursor solution.

Examples of a metal complex containing potassium include potassium 2-ethylhexanoate. Examples of a metal complex containing sodium include sodium 2-ethylhexanoate.

Examples of the metal complex containing niobium include niobium 2-ethylhexanoate. Specifically, as the metal complex containing niobium, niobium 2-ethylhexanoate is used, which does not show a peak in a range of 3 ppm or more and 5 ppm or less in proton nuclear magnetic resonance (NMR) measurement. Therefore, the niobium 2-ethylhexanoate contains few impurities. The niobium 2-ethylhexanoate may be free of impurities. Examples of the impurities include ethoxy groups derived from raw materials and ethanol produced as a by-product.

An organic solvent may be, for example, a mixed solvent of 2-ethylhexanoic acid and decane. A volume ratio of 2-ethylhexanoic acid to the entire organic solvent is, for example, 0.30 or more and 0.50 or less, and preferably 0.40 or more and 0.45 or less. A KNN precursor solution does not contain, for example, metal alkoxide or silicone oil.

A KNN volume concentration in the KNN precursor solution is, for example, more than 40 vol %, preferably 42 vol % or more and 60 vol % or less, more preferably 44 vol % or more and 55 vol % or less, and still more preferably 45 vol % or more and 50 vol % or less. When the KNN volume concentration is 42 vol % or more, a proportion of the organic solvent can be reduced, so that formation of cross-linking in drying and degreasing steps described later is not inhibited, and cross-linking of the piezoelectric layer 30 can be stabilized. In a KNN layer according to a CSD method, in a process of drying, degreasing, and firing, organic side chains and solvents around metal elements, K, Na, and Nb, are eliminated to form cross-linking, and finally become crystals. Therefore, by reducing a proportion of the organic solvent, cross-linking of the piezoelectric layer 30 can be stabilized. When the KNN volume concentration is 60 vol % or less, generation of bubbles in the KNN precursor solution can be reduced.

The “KNN volume concentration” is a sum of a volume of the potassium 2-ethylhexanoate, a volume of sodium 2-ethylhexanoate, and a volume of niobium 2-ethylhexanoate, relative to a volume of the entire KNN precursor solution.

A KNN mass concentration in the KNN precursor solution is, for example, 50 mass % or more and 70 mass % or less, preferably 52 mass % or more and 60 mass % or less, and more preferably 53.12 mass % or more and 58.08 mass % or less. When the KNN mass concentration is 50 mass % or more, the cross-linking of the piezoelectric layer 30 can be stabilized. When the KNN mass concentration is 70 mass % or less, generation of bubbles in the KNN precursor solution can be reduced.

The “KNN mass concentration” is a sum of a mass of potassium 2-ethylhexanoate, a mass of sodium 2-ethylhexanoate, and a mass of niobium 2-ethylhexanoate, relative to a total mass of a KNN precursor solution.

A KNN molar concentration in the KNN precursor solution is, for example, 10.0 mol/L or more and 15.0 mol/L or less, preferably 10.5 mol/L or more and 12.0 mol/L or less, and more preferably 10.83 mol/L or more and 11.84 mol/L or less. When the KNN molar concentration is 10.0 mol/L or more, the cross-linking of the piezoelectric layer 30 can be stabilized. When the KNN molar concentration is 15.0 mol/L or less, generation of bubbles in the KNN precursor solution can be reduced.

The “KNN molar concentration” is a sum of the number of moles of potassium 2-ethylhexanoate, the number of moles of sodium 2-ethylhexanoate, and the number of moles of niobium 2-ethylhexanoate dissolved in 1 L of the KNN precursor solution.

Next, the prepared KNN precursor solution is applied onto the orientation control layer 20 by spin coating or the like to form a KNN precursor layer. Next, the KNN precursor layer is heated, for example, at 130° C. or higher and 250° C. or lower and dried for a certain period of time, and the dried KNN precursor layer is further heated, for example, at 300° C. or higher and 450° C. or lower and held for a certain period of time to be degreased. Next, the degreased KNN precursor layer is crystallized by firing at, for example, 550° C. or higher and 800° C. or lower. A heating rate in the firing is, for example, 5° C./see or more and 15° C./see or less, and preferably 8° C./see or more and 12° C./see or less.

As described above, the crystal layer 32 made of the KNN layer can be formed. The above series of steps from the application of the KNN precursor solution to the firing of the KNN precursor layer are repeated a plurality of times. Accordingly, the piezoelectric layer 30 including the plurality of crystal layers 32 can be formed.

In forming the crystal layer 32, a heating device used for drying and degreasing the KNN precursor layer is, for example, a hot plate. A heating device used for firing the KNN precursor layer is an infrared lamp annealing (rapid thermal annealing: RTA) device.

Next, the second electrode 40 is formed on the piezoelectric layer 30. The second electrode 40 is formed by, for example, a sputtering method or a vacuum deposition method. Next, the second electrode 40 and the piezoelectric layer 30 are patterned by, for example, photolithography and etching. The second electrode 40 and the piezoelectric layer 30 may be patterned in separate steps.

The piezoelectric element 100 can be manufactured by the above steps.

### 3. Liquid Ejection Head

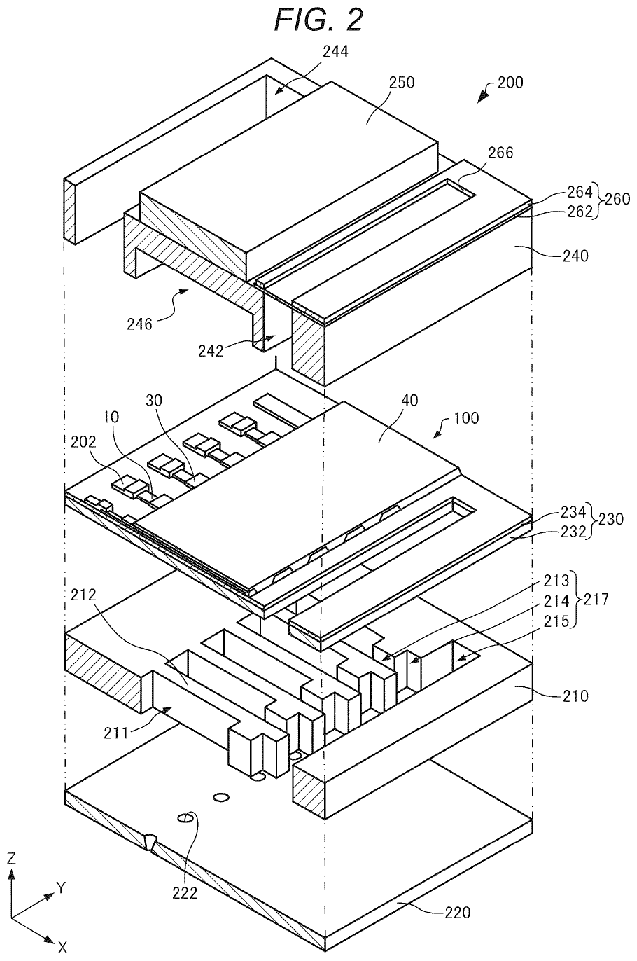

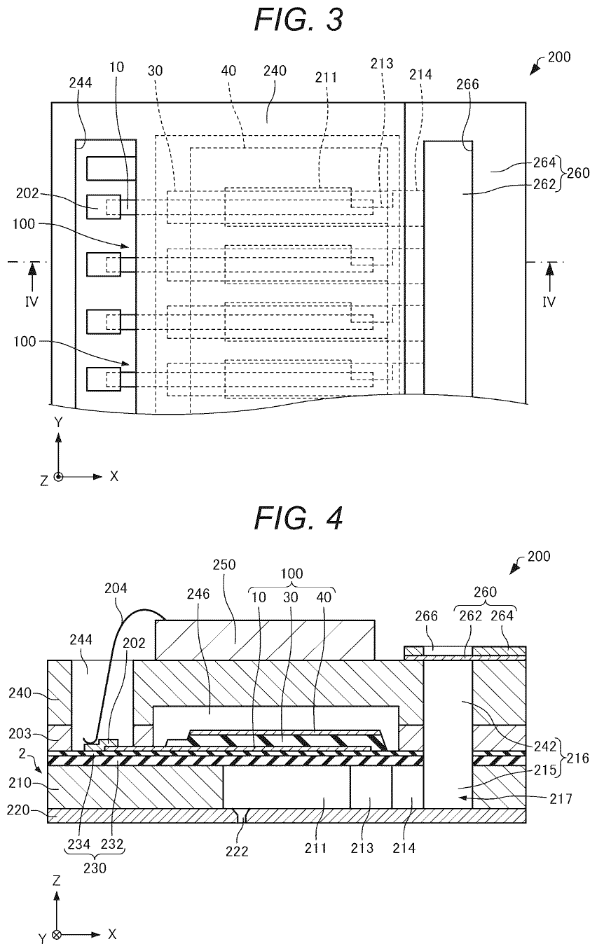

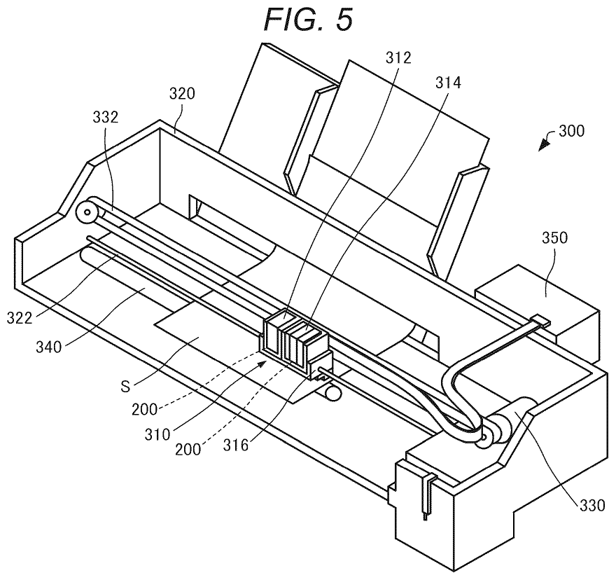

Next, the liquid ejection head according to the embodiment will be described with reference to the drawings. FIG. 2 is an exploded perspective view schematically showing a liquid ejection head 200 according to the embodiment. FIG. 3 is a plan view schematically showing the liquid ejection head 200 according to the embodiment. FIG. 4 is a cross-sectional view taken along a line IV-IV shown in FIG. 3, schematically showing the liquid ejection head 200 according to the embodiment. FIGS. 2 to 4 illustrate an X-axis, a Y-axis, and a Z-axis as three axes orthogonal to each other. In FIGS. 2 and 4, the piezoelectric element 100 is illustrated in a simplified manner.

As shown in FIGS. 2 to 4, the liquid ejection head 200 includes, for example, the substrate 2, the piezoelectric element 100, a nozzle plate 220, a protective substrate 240, a circuit substrate 250, and a compliance substrate 260. The substrate 2 includes a flow path forming substrate 210 and a vibration plate 230. For convenience, in FIG. 3, the circuit substrate 250 is not illustrated.

The flow path forming substrate 210 is, for example, a silicon substrate. A pressure generating chamber 211 is formed in the flow path forming substrate 210. The pressure generating chamber 211 is divided by a plurality of partition walls 212. A volume of the pressure generating chamber 211 is changed by the piezoelectric element 100.

A first communication path 213 and a second communication path 214 are formed at an end portion in a +X-axis direction of the pressure generating chamber 211 on the flow path forming substrate 210. The first communication path 213 is implemented in a manner that an opening area thereof is reduced by narrowing the end portion in the +X-axis direction of the pressure generating chamber 211 from a Y-axis direction. A size of the second communication path 214 in the Y-axis direction is, for example, the same as a size of the pressure generating chamber 211 in the Y-axis direction. A third communication path 215 communicating with the plurality of second communication paths 214 is formed in the +X-axis direction of second communication path 214. The third communication path 215 constitutes a part of a manifold 216. The manifold 216 serves as a common liquid chamber for the pressure generating chambers 211. Thus, a supply flow path 217 including the first communication path 213, the second communication path 214, and the third communication path 215, and the pressure generating chamber 211 are formed in the flow path forming substrate 210. The supply flow path 217 communicates with the pressure generating chamber 211 and supplies liquid to the pressure generating chamber 211.

The nozzle plate 220 is provided on one surface of the flow path forming substrate 210. A material for the nozzle plate 220 is, for example, steel use stainless (SUS). The nozzle plate 220 is bonded to the flow path forming substrate 210 by, for example, an adhesive or a heat-welded film. A plurality of nozzle holes 222 are formed in the nozzle plate 220 along the Y-axis. The nozzle hole 222 communicates with the pressure generating chamber 211 and is used for ejecting liquid.

The vibration plate 230 is provided on the other surface of the flow path forming substrate 210. The vibration plate 230 includes, for example, a silicon oxide layer 232 provided on the flow path forming substrate 210 and a zirconium oxide layer 234 provided on the silicon oxide layer 232.

The piezoelectric element 100 is provided, for example, on the vibration plate 230. For example, a plurality of piezoelectric elements 100 are provided. The number of the piezoelectric elements 100 is not particularly limited. For convenience, in FIG. 3, the orientation control layer 20 is not illustrated.

In the liquid ejection head 200, the vibration plate 230 and the first electrode 10 are displaced by the deformation of piezoelectric the layer 30 having electromechanical conversion characteristics. That is, in the liquid ejection head 200, the vibration plate 230 and the first electrode 10 substantially function as a vibration plate. The vibration plate 230 may be omitted, and only the first electrode 10 may function as the vibration plate. When the first electrode 10 is directly provided on the flow path forming substrate 210, it is preferable to protect the first electrode 10 by an insulating protective film or the like so that the first electrode 10 is not brought into contact with the liquid.

The first electrode e 10 is formed as an individual electrode independent for each pressure generating chamber 211. A size of the first electrode 10 in the Y-axis direction is smaller than a size of the pressure generating chamber 211 in the Y-axis direction. A size of the first electrode 10 in an X-axis direction is larger than a size of the pressure generating chamber 211 in the X-axis direction. In the X-axis direction, both end portions of the first electrode 10 are located outside both end portions of the pressure generating chamber 211. A lead electrode 202 is coupled to an end portion of the first electrode 10 in a −X-axis direction.

A size of the piezoelectric layer 30 in the Y-axis direction is, for example, larger than the size of the first electrode 10 in the Y-axis direction. A size of the piezoelectric layer 30 in the X-axis direction is, for example, larger than the size of the pressure generating chamber 211 in the X-axis direction. An end portion of the piezoelectric layer 30 in the +X-axis direction is, for example, located outside an end portion of the first electrode 10 in the +X-axis direction. The end portion of the first electrode 10 in the +X-axis direction is covered by the piezoelectric layer 30. On the other hand, an end portion of the piezoelectric layer 30 in the −X-axis direction is, for example, located inside an end portion of the first electrode 10 in the −X-axis direction. The end portion of the first electrode 10 in the −X-axis direction is not covered by the piezoelectric layer 30.

The second electrode 40 is, for example, provided continuously on the piezoelectric layer 30 and the vibration plate 230. The second electrode 40 is implemented as a common electrode shared by the plurality of piezoelectric elements 100.

The protective substrate 240 is bonded to the flow path forming substrate 210 by an adhesive 203. A through hole 242 is formed in the protective substrate 240. In the illustrated example, the through hole 242 penetrates the protective substrate 240 in a Z-axis direction and communicates with the third communication path 215. The through hole 242 and the third communication path 215 constitute the manifold 216 serving as the common liquid chamber for the pressure generating chambers 211. Further, the protective substrate 240 is formed with a through hole 244 that penetrates the protective substrate 240 in the Z-axis direction. An end portion of the lead electrode 202 is located in the through hole 244.

The protective substrate 240 is formed with an opening portion 246. The opening portion 246 is a space for not inhibiting driving of the piezoelectric element 100. The opening portion 246 may or may not be sealed.

The circuit substrate 250 is provided on the protective substrate 240. The circuit substrate 250 includes a semiconductor integrated circuit (IC) for driving the piezoelectric element 100. The circuit substrate 250 and the lead electrode 202 are electrically coupled via connection wiring 204.

The compliance substrate 260 is provided on the protective substrate 240. The compliance substrate 260 includes a sealing layer 262 provided on the protective substrate 240 and a fixing plate 264 provided on the sealing layer 262. The sealing layer 262 is a layer for sealing the manifold 216. The sealing layer 262 has, for example, flexibility. A through hole 266 is formed in the fixing plate 264. The through hole 266 penetrates the fixing plate 264 in the Z-axis direction. The through hole 266 is provided at a position overlapping the manifold 216 when viewed in the Z-axis direction.

### 4. Printer

Next, the printer according to the embodiment will be described with reference to the drawings. FIG. 5 is a perspective view schematically showing a printer 300 according to the embodiment.

The printer 300 is an inkjet printer. As shown in FIG. 5, the printer 300 includes a head unit 310. The head unit 310 includes, for example, liquid ejection heads 200. The number of liquid ejection heads 200 is not particularly limited. The head unit 310 has detachable cartridges 312 and 314 constituting a liquid supply unit. A carriage 316 on which the head unit 310 is mounted is provided on a carriage shaft 322 attached to a device main body 320 so as to be movable in an axial direction, and ejects liquid supplied from the liquid supply unit.

Here, the liquid refers to any material in a liquid phase, and liquid materials such as sols and gels are also included in the liquid. The liquid includes not only the liquid as a state of a substance, but also liquid in which particles of a functional material made of a solid such as a pigment or a metal particle are dissolved, dispersed, or mixed in a solvent. Representative examples of the liquid include ink and liquid crystal emulsions. The term ink includes various types of liquid compositions such as general water-based ink, oil-based ink, gel ink, and hot melt ink.

In the printer 300, a driving force of a drive motor 330 is transmitted to the carriage 316 via a plurality of gears (not shown) and a timing belt 332, so that the carriage 316 on which the head unit 310 is mounted is moved along the carriage shaft 322. Meanwhile, the device main body 320 is provided with a conveyance roller 340 serving as a conveyance mechanism for moving a sheet S, which is a recording medium such as paper, relative to the liquid ejection head 200. The conveyance mechanism that conveys the sheet S is not limited to the conveyance roller, and may be a belt, a drum, or the like.

The printer 300 includes a printer controller 350 serving as a control unit that controls the liquid ejection head 200 and the conveyance roller 340. The printer controller 350 is electrically coupled to the circuit substrate 250 of the liquid ejection head 200. The printer controller 350 includes, for example, a random access memory (RAM) that temporarily stores various types of data, a read only memory (ROM) that stores control programs and the like, a central processing unit (CPU), and a drive signal generation circuit that generates drive signals to be supplied to the liquid ejection head 200.

The piezoelectric element 100 can be used in a wide range of applications, not limited to a liquid ejection head and a printer. The piezoelectric element 100 is suitably used as, for example, an ultrasonic motor, a vibrating dust removal device, a piezoelectric transformer, a piezoelectric speaker, a piezoelectric pump, and a piezoelectric actuator in a pressure-electricity conversion device. The piezoelectric element 100 is suitably used as, for example, a piezoelectric sensor element such as an ultrasonic detector, an angular velocity sensor, an acceleration sensor, a vibration sensor, a tilt sensor, a pressure sensor, a collision sensor, a human sensor, an infrared sensor, a terahertz sensor, a heat detection sensor, a pyroelectric sensor, and a piezoelectric sensor. The piezoelectric element 100 is suitably used as a ferroelectric element such as a ferroelectric memory (FeRAM), a ferroelectric transistor (FeFET), a ferroelectric calculation circuit (FeLogic), and a ferroelectric capacitor. The piezoelectric element 100 is suitably used as a voltage-controlled optical element such as a wavelength converter, an optical waveguide, an optical path modulator, a refractive index control element, and an electronic shutter mechanism.

### 5. Examples and Comparative Examples

### 5.1. Preparation of Samples

### 5.1.1. Example 1

A front surface of a single crystal silicon substrate was thermally oxidized to form a SiO₂ layer having a thickness of 1460 nm. Next, a Zr film having a thickness of 400 nm was formed by a direct current (DC) sputtering method, and a Zro₂ layer was formed by subjecting the Zr film to a heat treatment at 850° C.

Next, as a first electrode, a Ti layer, a Pt layer, and an Ir layer having thicknesses of 20 nm, 80 nm, and 5 nm, respectively, were formed on the Zro₂ layer by a DC sputtering method.

Next, a BFTP precursor solution was prepared so as to have a molar ratio of Bi: Pb: Fe: Ti=110:10:50:50. Then, the prepared BFTP precursor solution was applied onto the Ir layer and the ZrO₂ layer by a spin coating method, dried at 180° C. for 3 minutes, degreased at 380° C. for 3 minutes, and fired at 650° C. for 3 minutes. As described above, a BFTP layer having a thickness of 20 nm was formed.

Next, a simple solution containing potassium 2-ethylhexanoate, sodium 2-ethylhexanoate, and niobium 2-ethylhexanoate was synthesized. A mixed solvent of 2-ethylhexanoic acid and decane was used as an organic solvent. A volume ratio of 2-ethylhexanoic acid to the entire organic solvent was set to 0.42. These simple solutions were prepared so as to be (K_{0.50}Na_{0.50})_{1.015}NbOₓ (where x is any number larger than 0) to obtain a KNN precursor solution. A KNN volume concentration in the KNN precursor solution was 50 volt. A KNN mass concentration in the KNN precursor solution was 58.08 mass %. A KNN molar concentration in the KNN precursor solution was 0.610 mol/L.

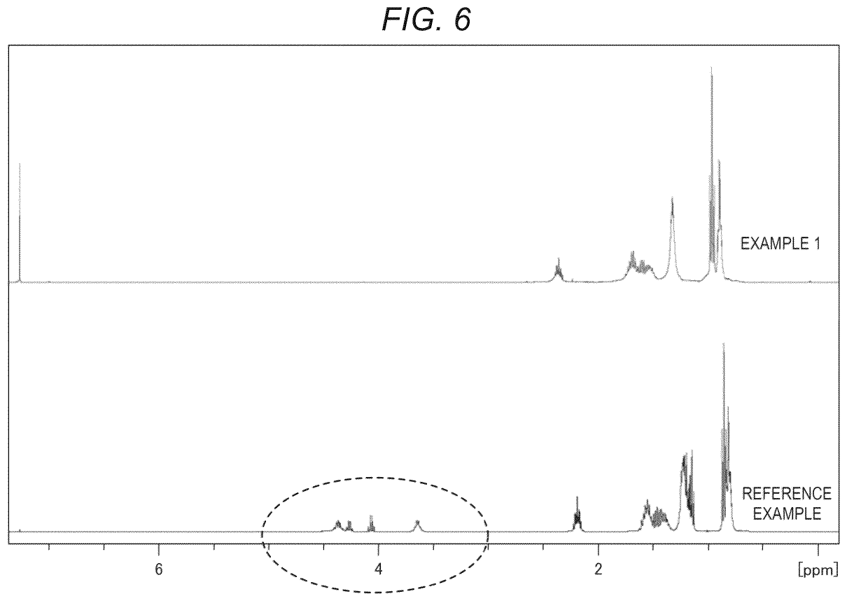

Here, FIG. 6 shows results of proton NMR measurement of the niobium 2-ethylhexanoate used in the KNN precursor solution. As an NMR device, “Ascend TM 400” manufactured by Bruker Corporation was used. Data analysis was performed using “TopSpin 4.2.0” manufactured by Bruker Corporation. CDCl₃ (400 MHZ, δ:7.26 ppm) was used as a deuterated solvent. Specifically, deuterated chloroform was used as a solvent and also as a standard substance, and a peak of the deuterated chloroform was set at 7.26 ppm for measurement.

As in “Example 1” shown in FIG. 6, no peak was observed in a range of 3 ppm or more and 5 ppm or less in an NMR measurement profile of the niobium 2-ethylhexanoate. Therefore, it can be seen that niobium 2-ethylhexanoate used in Example 1 does not contain impurities such as an ethoxy group derived from a raw material and an ethanol produced as a by-product. The KNN precursor solution was prepared using such niobium 2-ethylhexanoate.

On the other hand, as in “Reference Example” shown in FIG. 6, in a case of niobium 2-ethylhexanoate containing impurities, a peak is observed in a range of 3 ppm or more and 5 ppm or less in an NMR measurement profile. In FIG. 6, the peak is surrounded by a broken line.

Next, the prepared KNN precursor solution was applied onto the BFTP layer by a spin coating method, dried at 180° C. for 3 minutes, degreased at 380° C. for 3 minutes, and fired at 700° C. for 3 minutes. A heating rate for firing was 10° C./sec. As described above, a crystal layer having a thickness of 80 nm was formed. Then, a series of steps from the application of the KNN precursor solution to the firing of the KNN precursor layer was repeated five times to form a piezoelectric layer having a thickness of 400 nm and containing five crystal layers.

Next, a Pt layer having a thickness of 50 nm was formed on the piezoelectric layer by a DC sputtering method. Thereafter, the Pt layer was patterned by photolithography and etching to form a second electrode.

As described above, the piezoelectric element in Example 1 was formed.

### 5.1.2. Example 2

A piezoelectric element according to Example 2 was formed in a similar manner as in Example 1 described above except that a KNN volume concentration was 45 vol %, a KNN mass concentration was 53.12 mass %, and a KNN molar concentration was 0.549 mol/L in a KNN precursor solution.

### 5.1.3. Comparative Example 1

A piezoelectric element according to Comparative Example 1 was formed in a similar manner as in Example 1 described above except that a KNN volume concentration was 40 vol %, a KNN mass concentration was 48.02 masse, and a KNN molar concentration was 0.488 mol/L in a KNN precursor solution.

### 5.1.4. Comparative Example 2

A piezoelectric element according to Comparative Example 2 was formed in a similar manner as in Example 1 described above except that a KNN volume concentration was 35 vol %, a KNN mass concentration was 42.73 mass %, and a KNN molar concentration was 0.427 mol/L in a KNN precursor solution.

### 5.2. Experimental Condition

For an XRD device, “D8 DISCOVER with GADDS” manufactured by Bruker Corporation was used. The measurement was performed under conditions of 20=20° to 50° and 10 sec/° using Cu as a tube and a collimator having a diameter φ of 0.3 mm. Rocking curve measurement was performed at 2θ=21° to 24° and x=−95° to −85°.

### 5.3. Experimental Results

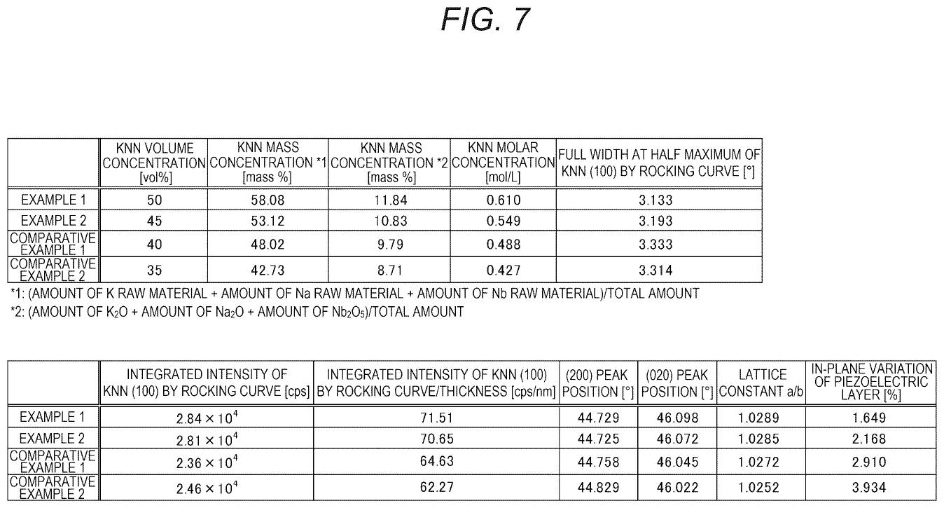

FIG. 7 is a table showing experimental results of Examples 1 and 2 and Comparative Examples 1 and 2. In FIG. 7, “KNN mass concentration *1” is a sum of a mass of potassium 2-ethylhexanoate, a of sodium 2-mass ethylhexanoate, and a mass of niobium 2-ethylhexanoate, relative to a total mass of a KNN precursor solution. “KNN mass concentration*2” is a sum of a mass of K₂O in potassium 2-ethylhexanoate, a mass of Na₂O in sodium 2-ethylhexanoate, and a mass of Nb₂O₅ in niobium 2-ethylhexanoate, relative to a total mass of a KNN precursor solution.

As shown in FIG. 7, in Examples 1 and 2, a “full width at half maximum of KNN (100) by rocking curve” was smaller than in Comparative Examples 1 and 2. That is, in Examples 1 and 2, a full width at half maximum of a peak derived from a (100) plane measured by the X-ray rocking curve method was smaller than that in Comparative Examples 1 and 2. Accordingly, it was found that Examples 1 and 2 had higher crystallinity than Comparative Examples 1 and 2. In Examples 1 and 2, since a KNN precursor solution having a higher KNN concentration was used compared with Comparative Examples 1 and 2, the “full width at half maximum of KNN (100) by rocking curve” could be made smaller.

As shown in FIG. 7, in Examples 1 and 2, a “full width at half maximum of KNN (100) by rocking curve/thickness” was larger than that t in Comparative Examples 1 and 2. That is, in comparison with Comparative Examples 1 and 2, Examples 1 and 2 had a larger integrated peak intensity derived from the (100) plane relative to a thickness of a piezoelectric layer, as measured by the X-ray rocking curve method. Accordingly, it was found that, compared with Comparative Examples 1 and 2, Examples 1 and 2 were able to improve an orientation in the (100) plane.

The thickness of the piezoelectric layer is an average thickness measured at 16 points at 0.5 mm intervals in a region centered on a center of a sample in a plan view and covering 32% of an area of the entire sample. The measurement was carried out using a laser ellipsometer “MARY-102” manufactured by Five Labs.

As shown in FIG. 7, in Examples 1 and 2, a “lattice constant a/b of KNN” was larger than that in Comparative Examples 1 and 2. Two or more peaks were observed between 2θ=44° to 47°, and a/b was obtained based on a ratio when a larger one of an inter-planar spacing obtained from the largest peak and the second largest peak according to the Bragg equation was defined as a numerator and a smaller one was defined as a denominator. The two large peaks observed between 2θ=44° to 47° were a peak derived from a (200) plane and a peak derived from a (020) plane.

As shown in FIG. 7, in Examples 1 and 2, an in-plane variation of the piezoelectric layer was smaller than that in Comparative Examples 1 and 2. The thickness of the piezoelectric layer was measured at 16 points at 0.5 mm intervals in a region centered on a center of a sample in a plan view and covering 32% of an area of the entire sample, and calculated as (maximum value−minimum value)/average value×100.

The embodiments and the modifications described above are examples, and the disclosure is not limited thereto. For example, the embodiments and the modifications may be combined as appropriate.

The present disclosure includes substantially the same configurations as the configurations described in the embodiment, such as a configuration having the same function, method, and result and a configuration having the same object and effect. The present disclosure includes a configuration in which a non-essential portion of the configuration described in the embodiments is replaced. The present disclosure includes a configuration capable of achieving the same function and effect or a configuration capable of achieving the same object as the configuration described in the embodiments. The present disclosure includes a configuration obtained by adding a known technique to the configuration described in the embodiments.

The following contents are derived from the embodiment and the modifications described above.

A piezoelectric element according to an aspect includes: a first electrode; a piezoelectric layer provided above the first electrode and containing a perovskite-type complex oxide containing potassium, sodium, and niobium; and a second electrode provided on or above the piezoelectric layer. The piezoelectric layer is preferentially oriented in a (100) plane, and a full width at half maximum of a peak derived from the (100) plane measured by an X-ray rocking curve method is 3.193° or less.

According to the piezoelectric element, the piezoelectric characteristics can be improved.

In the piezoelectric element according to the aspect, an integrated intensity of the peak derived from the (100) plane to a thickness of the piezoelectric layer may be 70.65 cps/nm or more.

According to the piezoelectric element, the orientation of the piezoelectric layer in the (100) plane can be improved.

In the piezoelectric element according to the aspect, a crystal structure of the perovskite-type complex oxide may be a tetragonal crystal represented by a=c≠b and a>b, where a, b, and c are lattice constants, and a/b may be 1.0285 or more.

According to the piezoelectric element, the full width at half maximum of the peak derived from the (100) plane of the piezoelectric layer measured by the X-ray rocking curve method can be reduced.

In the piezoelectric element according to the aspect, when a thickness of the piezoelectric layer is measured at 16 points, a value calculated by (maximum value−minimum value)/arithmetic average value×100 for the measured thickness may be 2.168 or less.

According to the piezoelectric element, a variation in the thickness of the piezoelectric layer can be reduced.

The piezoelectric element according to the aspect may further include an orientation control layer provided between the first electrode and the piezoelectric layer and containing bismuth, iron, titanium, and lead.

According to the piezoelectric element, an orientation of the piezoelectric layer can be controlled.

A liquid ejection head according to an aspect includes: the piezoelectric element according to the aspect; a flow path forming substrate formed with a pressure generating chamber having a volume changed by the piezoelectric element; and a nozzle plate having a nozzle hole which is formed therein and communicates with the pressure generating chamber.

A printer according to an aspect includes: the liquid ejection head according to the aspect; a conveyance mechanism configured to move a recording medium relative to the liquid ejection head; and a control unit configured to control the liquid ejection head and the conveyance mechanism.

What is claimed is:

1. A piezoelectric element comprising:
a first electrode;
a piezoelectric layer provided above the first electrode and containing a perovskite-type complex oxide containing potassium, sodium, and niobium; and
a second electrode provided on or above the piezoelectric layer, wherein
the piezoelectric layer is preferentially oriented in a (100) plane, and
a full width at half maximum of a peak derived from the (100) plane measured by an X-ray rocking curve method is 3.193° or less.

2. The piezoelectric element according to claim 1, wherein
an integrated intensity of the peak derived from the (100) plane to a thickness of the piezoelectric layer is 70.65 cps/nm or more.

3. The piezoelectric element according to claim 1, wherein
a crystal structure of the perovskite-type complex oxide is a tetragonal crystal represented by a=c≠b and a>b, where a, b, and c are lattice constants, and
a/b is 1.0285 or more.

4. The piezoelectric element according to claim 1, wherein
when a thickness of the piezoelectric layer is measured at 16 points, a value calculated by (maximum value−minimum value)/arithmetic average value×100 for the measured thickness is 2.168 or less.

5. The piezoelectric element according to claim 1, further comprising:
an orientation control layer provided between the first electrode and the piezoelectric layer and containing bismuth, iron, titanium, and lead.

6. A liquid ejection head comprising:
the piezoelectric element according to claim 1;
a flow path forming substrate formed with a pressure generating chamber having a volume changed by the piezoelectric element; and
a nozzle plate having a nozzle hole which is formed in the nozzle plate and communicates with the pressure generating chamber.

7. A printer comprising:
the liquid ejection head according to claim 6;
a conveyance mechanism configured to move a recording medium relative to the liquid ejection head; and
a control unit configured to control the liquid ejection head and the conveyance mechanism.
